(19) United States
(12) Patent Application Publication
(10) Pub. No.: US 2026/0005211 A1
(43) Pub. Date: Jan. 1, 2026

(54) SIGNAL AND/OR POWER ROUTING USING AT LEAST ONE INTERCONNECTION INTERPOSER IN A DIE STACK WITH AT LEAST ONE PASSIVE PASS-THROUGH DIE

(71) Applicant: ATI Technologies ULC, Thornhill (CA)

(72) Inventors: Tyrone HUANG, Ontario (CA); Wonjun JUNG, Ontario (CA); Yaser Azeez MOHAMMED, Ontario (CA)

(21) Appl. No.: 18/757,393

(22) Filed: Jun. 27, 2024

(51) Int. Cl. H01L 25/18; H01L 23/00; H01L 23/498; H10B 80/00

(52) U.S. Cl. CPC H01L 25/18; H01L 23/49827; H01L 24/08; H01L 24/80; H10B 80/00; H01L 24/16; H01L 2224/08235; H01L 2224/16235; H01L 2224/80895; H01L 2224/80896; H01L 2924/381

(57) ABSTRACT

An integrated circuit (IC) die stack is disclosed that routes signals and/or power around at least one active base die to die(s) above the at least one base die by using an interconnection interposer and at least one passive pass-through die. Through-silicon vias (TSV) and bond-pad vias (BPV) in the interconnection interposer and passive pass-through die(s) are used for signal connections between the base die, die(s) stacked above the base die and IC die stack substrate. Integration of complex electronic systems on a chip (SoC) can be inexpensively and quickly created using state of the art, off-the-shelf and unmodified IC devices.

### TECHNICAL FIELD

Embodiments of the present disclosure generally relate to integrated circuit packaging of a die stack, and in particular, to routing signals and/or power around an active base die to die(s) stacked above and/or below the base die using at least one interconnection interposer and at least one passive pass-through die.

### BACKGROUND

An active silicon integrated circuit die in a stacked die form (die stack) may require signals, e.g., analog and/or digital, to reach from the top mounted die(s) to the substrate ball/pad of the die stack. Traditional hybrid bonding uses through-silicon vias (TSVs) and bond-pad vias (BPVs) to connect these signals from the top mounted silicon die(s), through an active base die, to the die stack substrate having external connections for integration thereof into an electronic system. The active base die must be designed for and modified to accommodate connections for the signals from the top mounted die(s). The resources needed to correctly connect signals from the top mounted die(s) to the substrate ball/pads through the base die are quite costly due to active base die modifications and electro-static discharge (ESD) protection requirements for each signal. These resources include silicon area availability, floorplan flexibility and physical verification time, which in a complex active base die design is very limited already.

### SUMMARY

In one example of the disclosure, an integrated circuit (IC) die stack includes at least one active base die on a first layer of the IC die stack. At least one pass-through die on the first layer of the IC die stack. An interconnection interposer on a second layer of the IC die stack. At least one die on a third layer of the IC die stack. A substrate on a fourth layer of the IC die stack. Signal connections from the at least one die are coupled through the interconnection interposer and the at least one pass-through die to the substrate.

In one example of the disclosure, a method for routing signals, in an integrated circuit (IC) die stack, from at least one die around at least one active base die to a substrate includes coupling signals from the at least one die to an interconnection interposer. Coupling the signals from the interconnection interposer around the at least one active base die with at least one pass-through die and to the substrate.

In one example of the disclosure, a method for routing signals in an integrated circuit (IC) die stack includes coupling signals from at least one die around at least one active base die through at least one interconnection interposer and at least one pass-through die to a substrate.

In one example of the disclosure, a system on a chip (SoC) includes at least one integrated circuit (IC) die stack. Each of the at least one IC die stacks includes at least one active base die on a first layer of an IC die stack. A first at least one pass-through die on the first layer of the IC die stack. An interconnection interposer on a second layer of the IC die stack. A first at least one die on a third layer of the IC die stack. A substrate on a fourth layer of the IC die stack. Wherein signal connections from the at least one die are coupled through the interconnection interposer and the at least one pass-through die to the substrate.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates a schematic elevational cross-section layout of a prior art die stack.

FIG. 2 illustrates a representative schematic elevational cross-section layout of a die stack, according to an example.

FIG. 3 illustrates a representative schematic elevational cross-section layout of a die stack, according to another example.

FIG. 4 illustrates a representative schematic elevational cross-section layout of a die stack, according to yet another example.

FIG. 5 illustrates representative schematic plan view and elevational cross-section layouts of an interconnection interposer, according to examples.

FIG. 6 illustrates schematic plan and elevational cross-section views of the prior art die stack of FIG. 1.

FIG. 7 illustrates schematic plan and elevational cross-section views of die stacks similar to those shown in FIGS. 2, 3 and 4, according to examples.

FIG. 8 illustrates a representative schematic elevational cross-section layout of a die stack having at least one embedded device, according to yet another example.

FIG. 9 illustrates a representative schematic plan view of an interposer of the die stack illustrated in FIG. 8, according to an example.

FIG. 10 illustrates another representative schematic elevational cross-section layout of a die stack having a coreless interposer, according to another example.

FIG. 11 illustrates another representative schematic elevational cross-section layout of a die stack having at least one embedded device and an interposer having a multi-part core, according to yet another example.

FIG. 12 illustrates a representative schematic plan view of the multi-part core of the interposer of the die stack illustrated in FIG. 11, according to an example.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

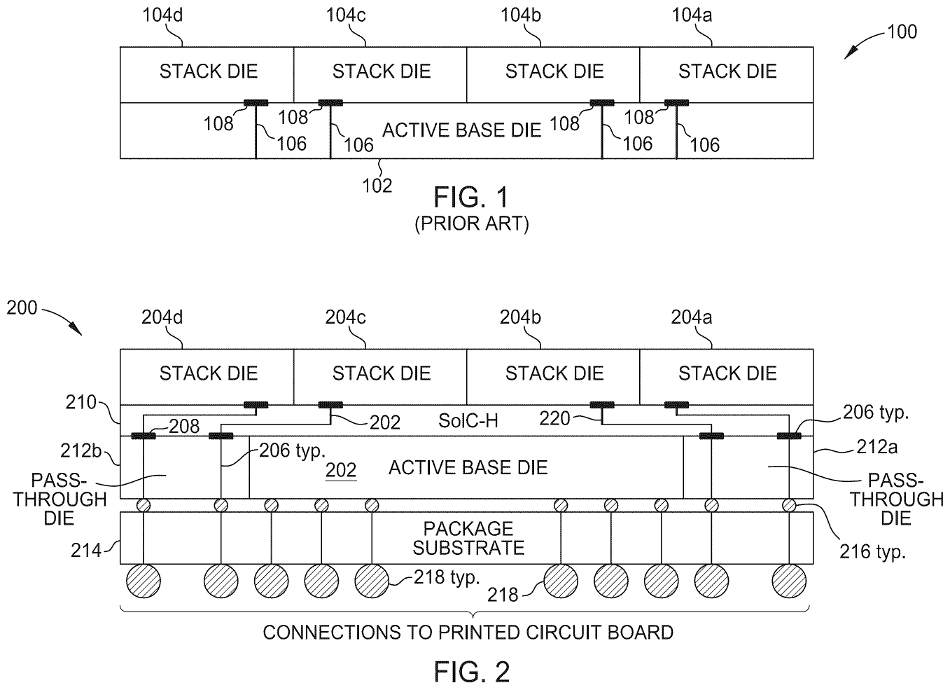

Referring to FIG. 1, depicted is a schematic elevational cross-section layout of a prior art die stack. An integrated circuit die stack, generally represented by the numeral 100, may comprise an active base die 102, a plurality of dice 104 coupled to the back side of (above) the active base die 102, at least one through-silicon vias (TSV) 106 for each one of the plurality of dice 104 and bond-pad vias (BPV) 108 for electrical connections between the dice 104 and the TSVs 106 in the active base die 102. The active base die 102 must be designed for and modified to accommodate connections (e.g., TSVs 106 and BPV 108) for the signals from the top mounted plurality of dice 104 therein above. The resources needed to correctly connect signals from the plurality of dice 104 to the substrate ball/pads (not shown) through the active base die 102 are quite costly due to modifications of the active base die 102, and electro-static discharge (ESD) protection requirements for each signal. These resources include silicon area availability, floorplan flexibility, and physical verification time, which in a complex active base die design is very limited already. An “active base die” comprises electronic circuits, e.g., interconnected transistors forming operational functions, such as for example but not limited to, microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit, tensor processing unit and the like. A passive die has no electronic circuits, only interconnecting conductive lands and through-silicon vias (TSV) for interconnection of dice stacked as more fully disclosed herein.

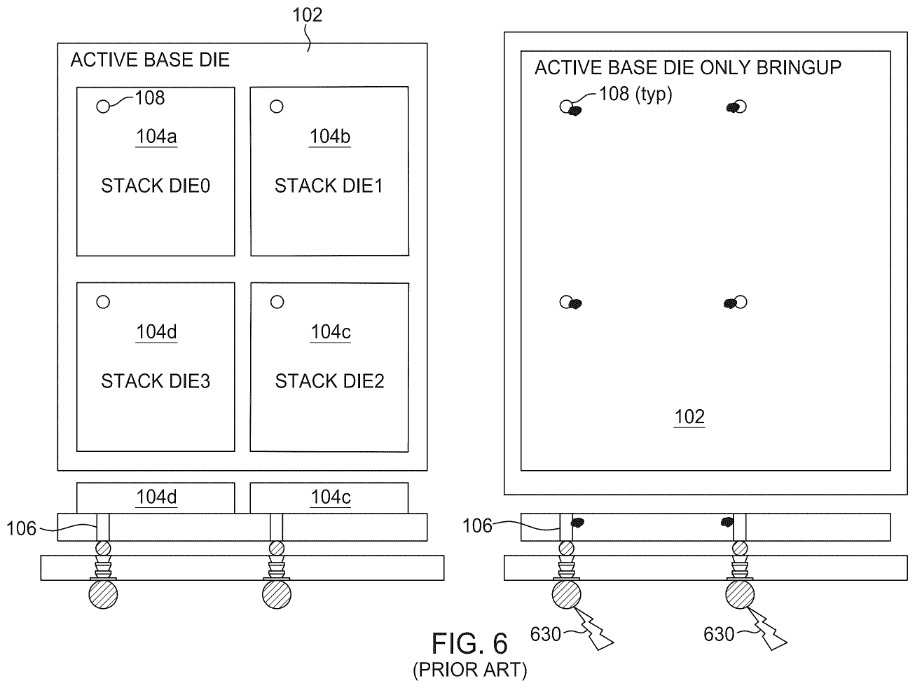

Referring to FIG. 6, depicted are schematic plan and elevational cross-section views of the prior art die stack of FIG. 1. The plan views of FIG. 6 show the dice 104 on the at least one active base die 102 with TSVs 106 and BPVs 108 going through the at least one active base die 102 for connection to the stack dice 104. An ESD event 630 on an external IC package connection to any one or more of the dice 104 may cause ESD damage to the internal circuits of the active base die 102 because the ESD event through the signal TSVs to the die 104 have to traverse through the active base die 102 structure.

Referring to FIG. 2, depicted is a representative schematic elevational cross-section layout of a die stack, according to an example. An integrated circuit (IC) die stack, generally represented by the numeral 200, may comprise at least one active base die 202, a plurality of dice 204, an interconnection interposer 210, at least one pass-through die 212, at least one through-silicon vias (TSV) 206 for each one of the dice 204, and bond-pad vias (BPV) 208 for electrical connections (hybrid bonding) between the dice 204 and a package substrate 214 through the at least one pass-through die 212. The at least one pass-through die 212 and the at least one active base die 202 may be electrically connected to the package substrate 214 with micro-bumps 216 and the like. The micro-bumps 216 and the like may be connected to a, external to the IC package of the integrated circuit die stack 200, ball/pin array 218 that may be used to connect to a printed circuit board (not shown) of an electronic system (not shown). The interconnection interposers, as disclosed herein, may comprise metal conductors arranged in layers of both horizontal and vertical conductors with insulating dielectric material therebetween, in a wafer (die) for re-routing interconnection points between active and/or passive dice above and/or below the interconnection interposers.

According to the teachings of this disclosure, at least one pass-through die 212 and an interconnection interposer 210 may be provided to avoid requiring integration of through-silicon vias (TSV) in the at least one active base die 202, e.g., processor, for signals and/or power to the dice 204 located above the at least one active base die 202. Signal lands 220 may connect various BPVs 208 together, top-to-bottom, top-to-top and/or bottom-to-bottom in the interconnection interposer 210. Not having to add TSVs in an existing design high-performance digital device, e.g., at least one active base die 202, may significantly reduce and/or eliminate digital device modification costs, and time to manufacture new products consisting of three-dimensional stacked memory and digital device organizations. This also allows the usage of leading-edge digital device nodes, without modification thereto, that have not yet been enabled nor have available options for incorporating TSVs in the high-performance digital device components thereof. This enables the manufacture of advanced state of the art products of three-dimensional stacked memory and digital device designs to use existing and unmodified high-performance state of the art digital devices. A digital device, e.g., at least one active base die 202, may be, for example but is not limited to, one or any combination of a microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit and tensor processing unit. The terms layer, device, die, silicon layer, silicon die, and silicon device may be used interchangeably herein.

An at least one active silicon device (die 204) used in a stacked die format may require analog and digital signals (and power) to reach from the die 204, mounted above, to the substrate 214 ball/pin array 218. Traditional hybrid bonding uses through-silicon vias (TSV) 206 and bond-pad vias (BPV) 208 to connect the (top mounted) plurality of dies 204 adjacent to each other to the package substrate 214 below, which requires extra design steps for the at least one base die 202 to accommodate the signals coming from the dies 204 to the package substrate 214. Extra design considerations take up valuable area in the base die 202 which is eliminated when routing signals around the base die 202 by using the interconnection interposer 210 between the die(s) 204, mounted above, and the passive pass-through dies 212 to the package substrate 214. Any signals (and/or power) can be routed away from the more expensive base die 202 and instead be route through the pass-through die 212 fitted with TSVs 206. It is contemplated and within the scope of this disclosure that a pass-through die 212 may be passive (TSVs only) or active (transistor devices and TSVs therein). The pass-through die 212 may also be referred to as a “chiplet” when containing active devices therein.

Another advantage in utilizing a pass-through die 212 with the interconnection interposer 210 is that any electrostatic discharge (ESD) vulnerable (susceptible) signal coupled to the top mounted die 204 can be safely routed to the package substrate 214 ball/pin array 218 without possibly affecting the active base die 202 it is stacked above. Since the pass-through die 212 may be passive, there could be potential cost savings by using older and larger technology nodes in such a die to create the TSV 206 arrays. Extra area costs and risk of ESD damage from signals associated with these top mounted stack dice 204 are thereby avoided, which further protects the electrical integrity of the at least one active base die 202. A separate passive pass-through base die 212 with just signal routing and TSVs 206 is a lower cost solution for providing required connectivity to the dice 204 without sacrificing any resource of the at least one active base die 202, thereby allowing for optimal base die area planning and maximizing performance thereof.

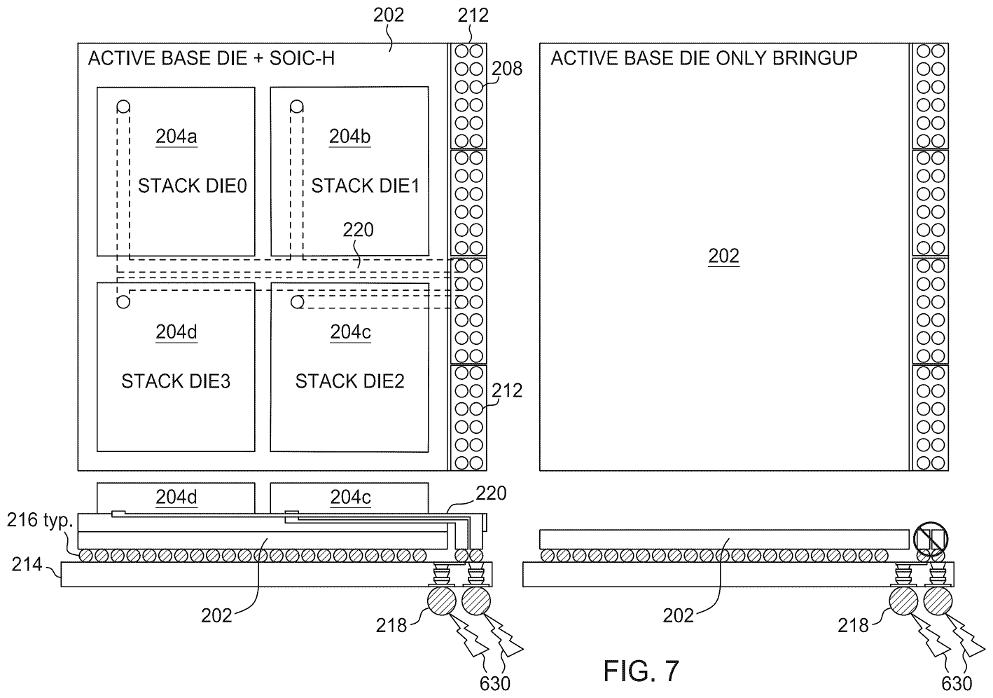

Referring to FIG. 7, depicted are schematic plan and elevational cross-section views of a die stack similar to the one shown in FIG. 2, according to examples. The plan views of FIG. 7 show the dice 104 on the active base die 102 having TSVs 106 and BPVs 108 going along the side of the at least one active base die 102 but not through for connection to the dice 104 through an interposer structure 210. An ESD event 630 on an external IC package connection to a die 204 cannot cause ESD damage to the internal circuits of the at least one active base die 202 because the signal TSVs 206 to the die 204 do not pass through the at least one active base die 102 structure, rather the ESD prone signals are only coupled through a pass-through die 212, which is electrically isolated from the at least one active base die 202.

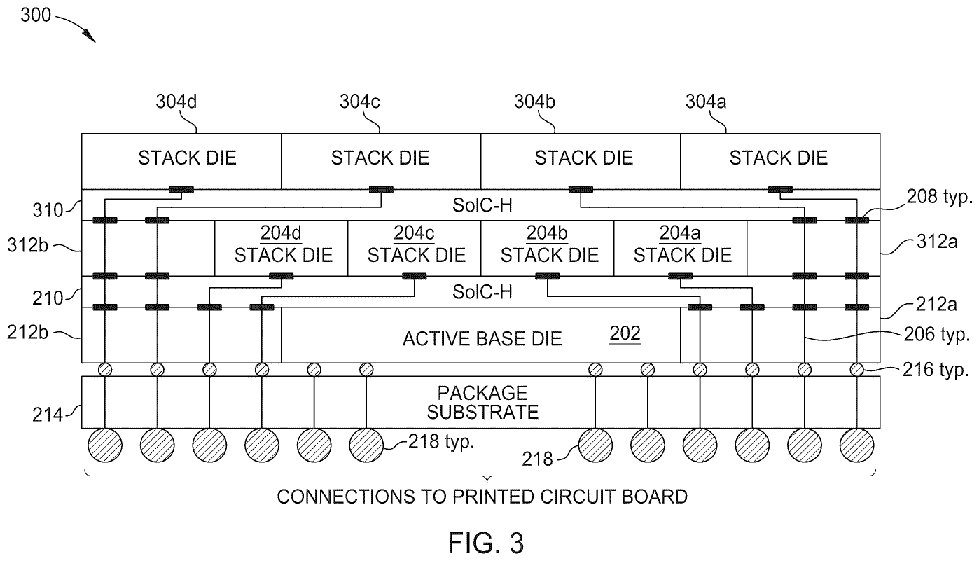

Referring to FIG. 3, depicted is a representative schematic elevational cross-section layout of a die stack, according to another example. An integrated circuit die stack, generally represented by the numeral 300, may comprise an at least one active base die 202, a first plurality of dice 204, a first interconnection interposer 210, a second interconnection interposer 310, a first at least one pass-through die 212, a second at least one pass-through die 312, a second plurality of dice 304, through-silicon vias (TSV) 206 for each one of the first and second dice 204 and 304, and bond-pad vias (BPV) 208 for electrical connections (hybrid bonding) between the first and second dice 204, 304, and a package substrate 214 through the first and second at least one pass-through dice 212, 312. The first and second at least one pass-through die 212, 312 and at least one active base die 202 may be electrically connected to the package substrate 214 with micro-bumps 216 and the like. The micro-bumps 216 and the like may be connected to a, external to the IC package of the integrated circuit die stack 300, ball/pin array 218 that may be used to connect to a printed circuit board (not shown) of an electronic system (not shown).

As disclosed in the description above of FIG. 2, neither the at least one active base die 202, nor the first and second stack dice 204, 304 need be modified in any way when creating a custom IC die stack 300. The at least one active dice 202, 204 and 304 may be individually tested before building the IC die stack 300, thus reducing die waste due to only one or two dice of the IC die stack found to be defective after the IC die stack has been fabricated. All customization of the IC die stack 300 may be accomplished using custom designed interconnection interposers 210 and 310, and first and second passive pass-through dies 212, 312. Fabrication yield and testing results are very good, as there may not be at least one active devices in the first and second passive pass-through dies 212, 312.

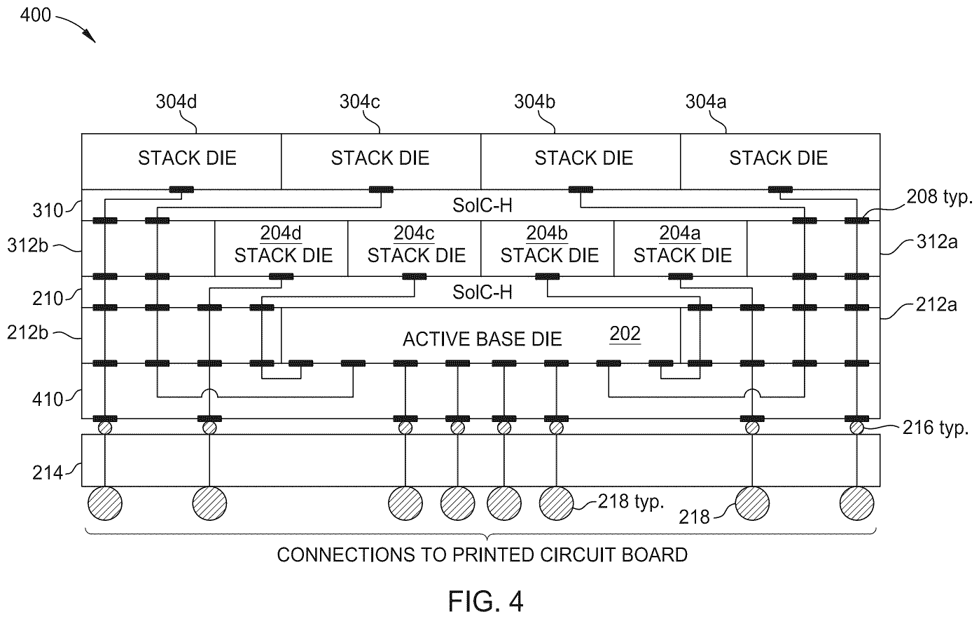

Referring to FIG. 4, depicted is a representative schematic elevational cross-section layout of a die stack, according to yet another example. An integrated circuit die stack, generally represented by the numeral 400, may comprise an at least one active base die 202, a first plurality of dice 204, a first interconnection interposer 210, a second interconnection interposer 310, a third interconnection interposer 410, a first at least one pass-through die 212, a second at least one pass-through die 312, a second plurality of dice 304, through-silicon vias (TSV) 206 for each one of the dice 204 and 304, and bond-pad vias (BPV) 208 for electrical connections (hybrid bonding) between the first and second dice 204, 304; first, second and third interconnection interposers 210, 310, 410; and the package substrate 214 through the at least one pass-through dice 212, 312 and the at least one active base die 202. The third interconnection interposer 410 may be electrically connected to the package substrate 214 with micro-bumps 216 and the like. The micro-bumps 216 and the like may be connected to a, external to the IC package of the IC die stack 400, ball/pin array 218 that may be used to connect to a printed circuit board (not shown) of an electronic system (not shown).

As disclosed in the descriptions above of FIGS. 2 and 3, neither the at least one active base die 202 nor the stack dice 204, 304 need be modified in any way when creating a custom IC die stack 400. The at least one active dice 202, 204 and 304 may be individually tested before building the die stack 300, thus reducing die waste due to only one or two dice of the die stack found to defective after the die stack has been fabricated. All customization of the die stack 400 may be accomplished using custom designed interconnection interposers 210, 310 and 410; and passive pass-through dies 212, 312. Fabrication yield and testing results are very good, as there may not be active devices in the passive pass-through dies 212, 312.

As shown in FIG. 4, some of the active base die 202 BPVs 208 may be directly coupled to the first and second stack dice 204 and 304 BPVs 208 through the interconnection interposers 210, 310 and 410. Any BPV 208 from one die may be coupled to any other BPV 208 of another die through a mapped connection configuration of one or more of the interconnection interposers 210, 310 and 410.

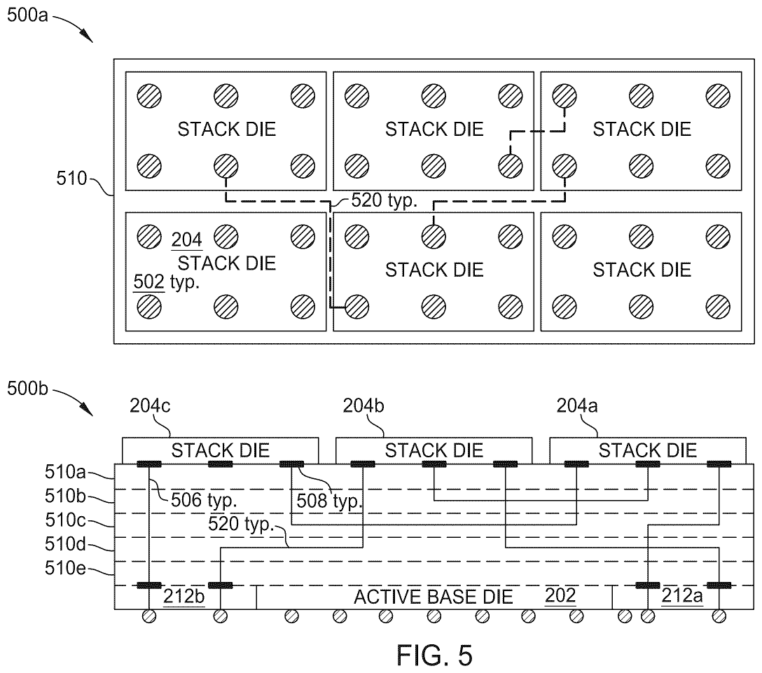

Referring to FIG. 5, depicted is a schematic plan view and elevational cross-section layouts of an interconnection interposer, according to examples. A plan view diagram is represented by the numeral 500a, and an elevational cross-section view diagram is represented by the numeral 500b. A plurality of dice 204 are located above a multi-layered interconnection interposer 510. The multi-layered interconnection interposer 510 may be configured for coupling signals from any of the plurality of dice 204 to selected ones of the micro-bumps 216 and/or other ones of the plurality of dice 204. Another interconnection interposer located below the at least one active base die 202 (see FIG. 4, interconnection interposer 410) may be used to couple signals from the plurality of dice 204 to the at least one active base die 202. Signals from the plurality of dice 204, coupled through the multi-layered interconnection interposer 510 are also coupled through passive pass-through dies 212 then on to the micro-bumps 216.

The structure and configuration of the multi-layered interconnection interposer 510 lends itself to complex signal routing between the at least one die 204 and active base die 202, and external IC package connections (ball/pin array 218), see FIGS. 2-4. The multi-layered interconnection interposer 510 may be thought of as an IC multilayer micro printed circuit comprising TSVs 206, BPVs 208 and connection lands 220 with insulating materials therebetween; all configured as a signal matrix patch panel. Signal crossovers may be done with connection lands 220 in different layers of the interconnection interposer 510, e.g., 510a-510e, with the lands 220 running through the different layers and connected together by TSVs 206, ultimately ending in the BPVs 208 on each side (face) of the interconnection interposer 510.

The multi-layered interconnection interposer 510 is representative of the interconnection interposers 210, 310 and 410, as shown in FIGS. 2, 3 and 4. Using multi-layered interconnection interposers 210, 310 and 410; standard, unmodified active IC dice 202 may be integrated together in an IC die stack package. Signal transitioning between different interconnection interposers at different levels in the IC die stack may be accomplished by using the passive pass-through dies 212 and 312 (FIGS. 2-4). Large scale and complex systems on a chip (SoC) may be quickly and inexpensively created, wherein the individual active die used therein may be pretested for proper operation before finally assembly in a SoC IC package. A further savings resulting from improved product yield.

For the examples disclosed above, connections between the vias (TSVs) of the active dice, interposer(s), substrate and passive pass-through dice may be done with lower resistance metal bonding pads, e.g., hybrid-bonding, copper hybrid-bonding instead of using micro-bumps in the power delivery paths and may significantly lower resistance of the electrical connections. This solves a significant voltage drop problem associated with using micro-bumps for electrical power circuit connections. An added benefit is elimination of the layer-to-layer (D2D) layers between the silicon wafers, allowing direct metal-to-metal electrical connections (hybrid-bonding) between layer layers, thereby further reducing the resistance of connections there between. In addition, the layer stack thickness will be reduced and heat transfer improved there through.

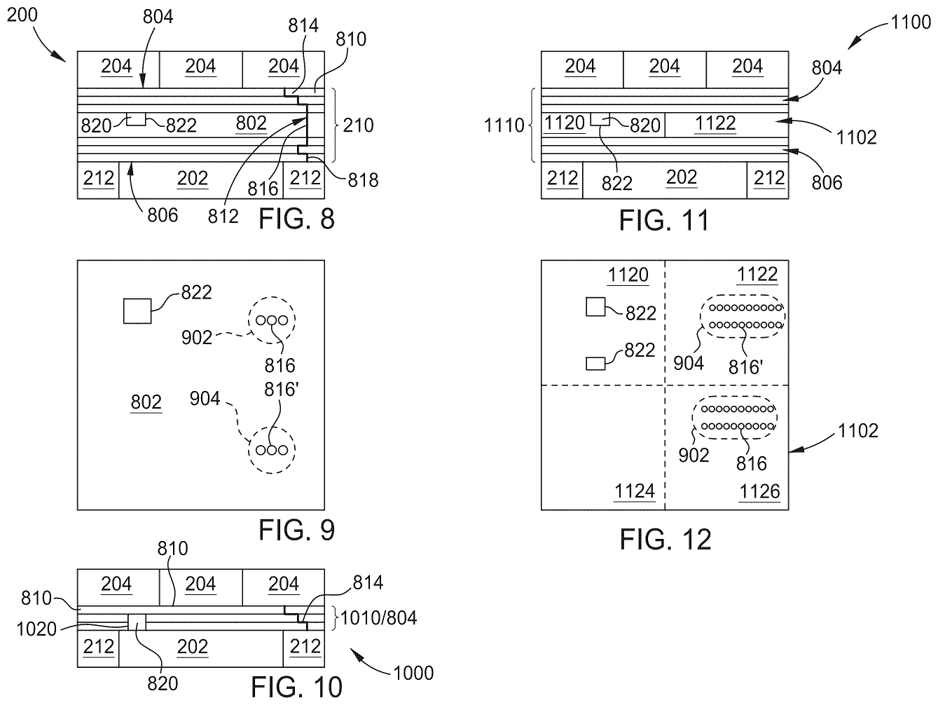

FIG. 8 illustrates a representative schematic elevational cross-section layout of the die stack 200 having at least one embedded device 820, according to yet another example. The package substrate is not shown in the die stack 200 depicted in FIG. 8. The die stack 200 is generally the same as described above, except that the interposer 210 disposed between the active base die 202 and the dice 204 includes an imbedded device 820. The imbedded device 820 may be an active device or a passive device. Examples of passive devices include capacitors, inductors, resistors, and the like. Examples of active devices include diodes, rectifiers, varactors, transistors, thryistors, voltage regulator circuitry, and the like. The imbedded device 820 is disposed in a cavity 822 formed in a core 802 of the interposer 210. The core 802 may be fabricated from glass, silicon or other suitable rigid dielectric material. A first redistribution layer 804 is disposed between the core 802 and the dice 204. An optional second redistribution layer 804 is disposed between the core 802 and the active base die 202 and pass through die 212. Conductive routings 814 (one of which is shown) pass through the interposer 210 to connect the dice 204 to the active base die 202 and pass through dies 212.

The first redistribution layer 804 includes a first portion 814 of the routings 812 (one of which is shown) formed in a plurality of dielectric layers 810. The first portion 814 of the routings 814 include vias and lines, which can be fabricated from copper or other suitable electrical conductor. One end of first portion 814 of the routings 812 connect to the functional circuitry of the dice 204, while the other end of the first portion 814 of the routings 812 connect to vias 816 formed through the core 802. The second redistribution layer 804, when present, includes a second portion 818 of the routings 812 that connect the vias 816 to the active base die 202 and pass through dies 212.

FIG. 9 illustrates a representative schematic plan view of the interposer 802 of the die stack 200 illustrated in FIG. 8, according to an example. The interposer 802 may include a first region 902 having vias 816 having a first pitch and first diameter. The interposer 802 optionally may include one or more second regions 904 having vias 816′ having a second pitch and/or second diameter. One or both of the pitch and diameter of the vias 816′ formed through the second region 904 may be different than the pitch and/or diameter of the vias 816 formed through the second region 902. In the example depicted in FIG. 9, the interposer 802 is a singular contiguous mass of material.

FIG. 10 illustrates another representative schematic elevational cross-section layout of a die stack 1000 having a coreless interposer 1010, according to another example. The package substrate is not shown in the die stack 1000 depicted in FIG. 10. The die stack 1000 is essentially the same as the die stack 200 described about except that the interposer 1010 consists essentially of the first redistribution layer 804, and does not include a core 802 or second redistribution layer 806. The interposer 1010 may optionally include at least one embedded device 820 disposed in a cavity 1020 formed in the dielectric layers 810.

FIG. 11 illustrates another representative schematic elevational cross-section layout of a die stack 1100 having at least one embedded device 820 and an interposer 1110 having a multi-part core 1102, according to yet another example. FIG. 12 illustrates a representative schematic plan view of the multi-part core 1102 of the interposer 1110 of the die stack 1100 illustrated in FIG. 11. The package substrate is not shown in the die stack 1100 depicted in FIG. 11.

The die stack 1100 is essentially the same as the die stack 200 described about except that the core 1102 of the interposer 1110 include multiple, separate and discrete segments. Although four core segments 1120, 1122, 1124, 1126 are illustrated in FIGS. 11 and 12, the number of core segments can vary as needed. The core segments 1120, 1122, 1124, 1126 may be the same or different. For example, one core segment 1120 may include cavities 822 for the embedded devices 820. In another example, two of the core cores (1122, 1126 as an example) are fabricated from different wafers. One core segment 1122 may include vias 816′ disposed in a region 904 having a first pitch and diameter, while another core segment 1126 may include vias 816 disposed in a region 906 having a second pitch and second diameter that is different than the pitch and/or diameters of the vias 816′ formed through the core segment 1126.

In the examples disclosed hereinabove, the various semiconductor dice are illustrated or otherwise presumed to be “face down” (e.g., back end of line—BEOL metal layers facing toward the bottom of the stack, bulk silicon/backside facing upward toward the top of the stack). However, different examples may utilize one or more chiplets or other silicon components in “face up” orientations as well.

It is contemplated and within the scope of this disclosure that all methods and forms, now and in the future, of electrical interconnection between dice known to those skilled in the art of semiconductor integrated circuit die stack configurations may be utilized in the examples disclosed and claimed herein.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed:

1. An integrated circuit (IC) die stack, comprising:
at least one active base die on a first layer of the IC die stack;
a first at least one pass-through die on the first layer of the IC die stack;
a first interconnection interposer on a second layer of the IC die stack;
a first at least one die on a third layer of the IC die stack; and
a substrate on a fourth layer of the IC die stack, wherein signal connections from the first at least one die are coupled through the first interconnection interposer and the first at least one pass-through die to the substrate.

2. The IC die stack according to claim 1, wherein the second layer is between the first and third layers, and the fourth layer is on an opposite side of the first layer from the second layer.

3. The IC die stack according to claim 2, further comprising:
a second at least one pass-through die on the third layer of the IC die stack;
a second interconnection interposer on a fifth layer of the IC die stack; and
a second at least one die on a sixth layer of the IC die stack, wherein signal connections from the second at least one die are coupled through the second interconnection interposer, the second at least one pass-through die and the first at least one pass-through die to the substrate.

4. The IC die stack according to claim 3, wherein the fifth layer is between the third and sixth layers.

5. The IC die stack according to claim 4, further comprising:
a third interconnection interposer on a seventh layer of the IC die stack;
wherein signal connections from the second at least one die are coupled through
the second interconnection interposer,
the second at least one pass-through die,
the first interconnection interposer,
the first at least one pass-through die, and
the third interconnection interposer to the substrate;
wherein signal connections from the first at least one die are coupled through
the first interconnection interposer,
the first at least one pass-through die, and
the third interconnection interposer to the substrate; and
wherein signal connections from the at least one active base die are coupled through the third interconnection interposer to the substrate.

6. The IC die stack according to claim 5, wherein the seventh layer is between the first and fourth layers.

7. The IC die stack according to claim 1, wherein the at least one active base die is selected from the group consisting of any one or a combination of a microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit and tensor processing unit.

8. The IC die stack according to claim 1, wherein the interconnection interposer includes one or more embedded devices.

9. The IC die stack according to claim 8, wherein the signal connections are made with through-silicon vias (TSVs); and
wherein the TSVs in the first, second and third interconnection interposers, and first and second at least one pass-through dies are coupled together with bond-pad vias (BPVs).

10. The IC die stack according to claim 9, wherein the at least one active base die signal connections are coupled to the substrate with bond-pad vias (BPVs).

11. The IC die stack according to claim 5, wherein at least one signal of the first or second at least one die is analog.

12. The IC die stack according to claim 5, wherein at least one signal of the first or second at least one die is digital.

13. The IC die stack according to claim 5, wherein at least one signal of the first or second at least one die is power.

14. The IC die stack according to claim 9, wherein each of the first, second and third Interconnection interposers comprise:
a plurality of conductive lands, each on a different level with insulation there between and patterned to match desired connection configurations thereof; and
the TSVs connect together the patterns of the conductive lands on different levels for the desired connection configurations.

15. The IC die stack according to claim 14, where the TSVs are connected to the BPVs on the interconnection interposers according to the desired connection configurations.

16. A method for routing signals, in an integrated circuit (IC) die stack, from at least one die around at least one active base die to a substrate, comprising:
coupling the signals from the at least one die through a first interconnection interposer and with a first pass-through die stacked with the first interconnection interposer, the first pass-through die disposed in a common tier with at least one active base die; and
coupling the signals passing through the first pass-through die and the first interconnection interposer to the substrate.

17. The method of claim 16, further comprising:
coupling the signals from the at least one die through a second interconnection interposer to a second pass-through die; and
coupling the signals from the second pass-through die to the first interconnection interposer.

18. A system on a chip (SoC), comprising:
at least one integrated circuit (IC) die stack in a computer system, each of the at least one IC die stacks comprising:
at least one active base die on a first layer of the at least one IC die stack;
at least one pass-through die on the first layer of the at least one IC die stack;
an interconnection interposer on a second layer of the at least one IC die stack;
at least one die on a third layer of the at least one IC die stack;
a substrate on a fourth layer of the at least one IC die stack, wherein signal connections from the at least one die are coupled through the interconnection interposer and the at least one pass-through die to the substrate; and
a memory and memory controller of the computer system coupled to the substrate and adapted for passing data between the at least one active base die of each of the IC die stacks and the computer system memory.

19. The SoC according to claim 18, wherein at least some of the signal connections from at least two of the at least one IC die stack are coupled together through the substrate.

20. The SoC according to claim 19, wherein the substrate is coupled to a printed circuit board of the computer system and provides the signal connections through the printed circuit board to the computer system for passing data there between.
